(19) United States
(12) Patent Application Publication
(10) Pub. No.: US 2007/0263445 A1
(43) Pub. Date: Nov. 15, 2007

(54) Non-volatile memory cell array

(76) Inventors: Walter von Emden, Dresden (DE); Georg Tempel, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/434,604

(22) Filed: May 15, 2006

(51) Int. Cl. G11C 16/04; G11C 11/34

(52) U.S. Cl. 365/185.12; 365/185.01

(57) ABSTRACT

One aspect of the invention relates to a non-volatile memory cell array and a fabrication method thereof. The non-volatile memory cell array includes first wordlines running in parallel along a first direction as well as second wordlines running in parallel along a second direction. Said first wordlines provide gate electrodes of a first part of non-volatile memory cells arranged along said second direction, whereas said second wordlines provide gate electrodes of a second part of non-volatile memory cells arranged along said first direction.

### BACKGROUND

One embodiment of the invention relates to a non-volatile memory cell array and to a fabrication method thereof.

Development of present and future non-volatile memory cell arrays is driven by the demand to increase the storage density per unit area on a semiconductor chip in order to reduce the average costs per bit. Apart from shrinking minimum feature sizes using advanced lithography memory cell array designs allowing for an increased number of storage bits per memory unit cell would be highly desirable.

### SUMMARY

One embodiment of the invention provides a plurality of memory cell transistors sub-divided in a first part of memory cell transistors and a second part of memory cell transistors, each of said plurality of memory cell transistors including source/drain regions, a plurality of first wordlines running in parallel along a first direction and a plurality of second wordlines running in parallel along a second direction, wherein said first wordlines provide gate electrodes to said first part of memory cell transistors and wherein said second wordlines provide gate electrodes to said second part of memory cell transistors, a dielectric material sandwiched in-between said first wordlines and said second wordlines at intersections thereof, and a plurality of bitlines running in parallel along a third direction, said plurality of bitlines being in electrical contact with said source/drain regions.

According to one embodiment of the invention a method of forming a non-volatile memory cell array includes forming an insulating structure within a semiconductor substrate, said insulating structure including an array of insulating regions, said insulating regions being consecutively arranged along first lines running in parallel along a first direction as well as along second lines running in parallel along a second direction, forming, along said first direction, parallel lines including a first dielectric layer stack over said substrate surface and said insulating regions, a first conductive layer covering said first dielectric layer stack and a first insulating coating structure surrounding said first conductive layer, forming, along said second direction, parallel lines including a second dielectric layer stack over said semiconductor substrate, a second conductive layer covering said second dielectric layer stack and a second insulating coating structure surrounding said second conductive layer, so that intersections of said lines along said first and second direction are congruent with said insulating regions, forming doped semiconductor zones within said semiconductor substrate in regions where said semiconductor substrate is not covered by said first or second dielectric layer stacks, forming contact plugs onto said doped semiconductor zones, and forming parallel bitlines running along a third direction, said bitlines electrically contacting said contact plugs.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by the reference to the following detailed description. The elements of the drawings are not necessarily drawn to scale relative to each other. Like reference numerals designate corresponding similar parts.

FIG. 1 illustrates a schematic top view of a non-volatile memory cell array according to an embodiment of the invention.

FIG. 2 illustrates a schematic top view of a single memory unit cell of the embodiment shown in FIG. 1.

FIG. 3 illustrates a schematic side view of the embodiment shown in FIG. 1.

FIG. 4 illustrates a schematic top view of the embodiment shown in FIG. 1 at the time of addressing a memory cell running in a first direction.

FIG. 5 illustrates a schematic top view of the embodiment shown in FIG. 1 at the time of addressing a memory cell running in a second direction.

FIGS. 6A to 6D are schematic views illustrating operating schemes when programming different bits of a single memory unit cell according to one embodiment of the invention.

FIGS. 7 to 19 are schematic cross-sectional views during fabrication of the non-volatile memory cell array shown in FIG. 1.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

According to one aspect of the invention, a non-volatile memory cell array includes a plurality of memory cell transistors including source/drain regions positioned along first lines running in parallel along a first direction and second lines running in parallel along a second direction, a plurality of first wordlines running in parallel along said first direction, said first wordlines providing gate electrodes to those of said plurality of memory cell transistors that run along said second direction, a plurality of second wordlines running in parallel along said second direction, said second wordlines providing gate electrodes to those of said plurality of memory cell transistors that run along said first direction, said second wordlines being formed over said first wordlines at intersections thereof, a dielectric material sandwiched between said first and second wordlines at said intersections, and a plurality of bitlines running in parallel along a third direction, said plurality of bitlines being in electrical contact with said source/drain regions.

Said first wordlines, second wordlines and bitlines are in one case arranged above a surface of a semiconductor substrate, said source/drain regions being formed within said semiconductor substrate. A single memory cell transistor running along said first direction includes, within said semiconductor substrate and arranged along said first direction, a source/drain region, a channel region and a further source/drain region. Likewise, a single memory cell transistor arranged along said second direction also includes, within said semiconductor substrate and arranged along said second direction, a source/drain region, a channel region and a further source/drain region.

The dielectric material isolates first and second wordlines from each other at the intersections. The bitlines may be provided above said first and second wordlines, for example. As a charge storage region for said plurality of memory cell transistors dielectric layer stacks sandwiched between respective channel regions and gate electrodes may be provided.

According to one aspect of the invention, a non-volatile memory cell array includes a plurality of memory cell transistors sub-divided in a first part of memory cell transistors and a second part of memory cell transistors, each of said plurality of memory cell transistors including source/drain regions, a plurality of first wordlines running in parallel along a first direction and a plurality of second wordlines running in parallel along a second direction, wherein said first wordlines provide gate electrodes to said first part of memory cell transistors and wherein said second wordlines provide gate electrodes to said second part of memory cell transistors, a dielectric material sandwiched in-between said first wordlines and said second wordlines at intersections thereof, and a plurality of bitlines running in parallel along a third direction, said plurality of bitlines being in electrical contact with said source/drain regions.

Although memory cell transistors of said first part and said second part may include a common structure, memory cells of said first part differ from memory cells of said second part by their alignment. The first, second and third directions in one case lie parallel to a surface of said semiconductor substrate, however, these directions are inclined to each other.

Again, a charge storage region may be provided for said plurality of memory cell transistors by a dielectric layer stack sandwiched between respective channel regions and gate electrodes thereof. Electrical contact of said bitlines with said source/drain regions may be provided by contact plugs, for example.

In one case, said first part of memory cell transistors run along said first direction and said second part of memory cell transistors run along said second direction. Thus, by addressing memory cell transistors arranged along said first and second directions by separate wordlines, it becomes possible to provide a compact memory cell design allowing for enlarged bit storage capacity.

An embodiment of a non-volatile memory cell array in one case further includes a plurality of insulating regions formed within a semiconductor substrate congruent with said intersections. Thus, said insulating regions lie below cross-points of said first and second wordlines. Said insulating regions provide an electrical isolation between channel regions of neighboring two memory cell transistors arranged along said first direction as well as between neighboring two memory cell transistors arranged along said second direction. Thus, the insulating regions are formed in-between channel regions of two neighboring memory cell transistors that are positioned along the same direction.

In one case, said non-volatile memory cell array includes at least one of the group of shallow trench isolation (STI), LOCOS (local oxidation of silicon) and deep trench isolation as said insulating regions. Said insulating regions may include an insulating material, for example, an oxide of silicon. However, further insulating materials may be used and appropriately chosen by the skilled person. Selection of said insulating materials may depend up on the material of said semiconductor substrate, for example. The semiconductor substrate may include one of Si, Ge, SiGe, III-V compound semiconductors such as GaAs, for example. However, further semiconducting materials may be used.

In one case, each of said plurality of memory cell transistors includes two source/drain regions, wherein each of said source/drain regions is shared between neighboring two of said plurality of memory cell transistors running in said first direction as well as between neighboring two of said plurality of memory cell transistors running in said second direction, and each of said source/drain regions is formed in said semiconductor substrate laterally positioned in-between two neighboring of said first wordlines and in-between two neighboring of said second wordlines. Thus, each of said source/drain regions serves as a source/drain region for four memory cell transistors, thereby providing a compact memory cell design. Considering a single source/drain region within said non-volatile memory cell array, there is abutting a first channel region on a first side of said source/drain region (e.g., from above with respect to a top view), a second channel region is abutting on a second side of said source/drain region (e.g., from the right with respect to a top view), a third channel region is abutting on a third side of said source/drain region (e.g., from below with respect to a top view) and a fourth channel region is abutting on a fourth side of said source/drain region (e.g., from the left with regard to a top view). Thus, a single memory unit cell is divided in four memory cell parts, a first part corresponding to a source/drain region, a second part corresponding to a channel region of a memory cell transistor arranged along said first side, a third part corresponding to a channel region of a memory cell transistor arranged along said second direction and a fourth part corresponding to said insulating region.

When forming said memory cells as NROM (nitrided-read-only-memory)-memory cells two bits may be stored in each channel region. Thus, according to one embodiment of the invention, four bits may be stored within a single memory unit cell.

According to an embodiment of the invention, a non-volatile memory cell array includes a first dielectric layer stack structure sandwiched between a surface of said semiconductor substrate and said first wordlines, said first dielectric layer stack structure being congruent with said first wordlines and providing a charge storage region to those of said memory cell transistors that run along said second direction; and a second dielectric layer stack structure sandwiched between said surface of said semiconductor substrate and said second wordlines, said second dielectric layer stack structure being congruent with said second wordlines and providing a charge storage region to those of said memory cell transistors that run along said first direction.

Said first dielectric layer stack may include parallel lines of first dielectric layers covering channel regions of memory cell transistors arranged along said second direction as well as insulating regions. Thus, merely that part of said first dielectric layer stack that covers a respective channel region serves as a charge storage region. Likewise, said second dielectric layer stack structure may include parallel lines of second dielectric layers running along said second direction covering respective channel regions, that is, respective surface parts of said semiconductor substrate, as well as parts of said first wordlines at intersections of said first and second wordlines.

In one case, said first and second dielectric layer stack structures include an ONO-(oxide-nitride-oxide)-stack. It is thus possible to provide non-volatile NROM memory cells.

According to one embodiment of the invention, said first and second directions are perpendicular to each other, said third direction being inclined to said first and second directions by an angle of 45°. Thus, said bitlines run along a diagonal of said first and second wordlines. Electrical contact of said source/drain regions may be provided by contact-plugs to said bitlines.

However, said first, second and third directions may include further angles relative to each other. Furthermore, said first and second wordlines as well as said bitlines may be formed as straight lines, although further line formations such as meanders or wavelike lines may also be realized.

In one case, said non-volatile memory cell array includes NROM memory cells. Thus, it is possible to store two bits per memory cell transistor leading to an overall storage capacity of four bits per memory unit cell according to one embodiment of the invention.

According to one aspect of the invention there is provided a non-volatile memory cell array, including a plurality of first wordlines running in parallel along a first direction, a plurality of second wordlines running in parallel along a second direction, said first and second wordlines being isolated from each other at intersections thereof by a dielectric material sandwiched therebetween, a plurality of source/drain regions, wherein each one of said plurality of source/drain regions is formed within a semiconductor substrate laterally positioned in-between two neighboring of said first wordlines and in-between two neighboring of said second wordlines and wherein neighboring two of said plurality of source/drain regions in said first direction define source and drain of a memory cell transistor including one of said second wordlines as a gate electrode, and wherein neighboring two of said plurality of source/drain regions in said second direction define source and drain of a memory cell transistor comprising one of said first wordlines as a gate electrode, and a plurality of bitlines running in parallel along a third direction, said plurality of bitlines providing electrical contact to said plurality of source/drain regions.

In one case, a first dielectric layer stack structure is sandwiched between said semiconductor substrate and said first wordlines, said first dielectric layer stack structure being congruent with said first wordlines and providing a charge storage region to those of said memory cell transistors that run along said second direction, and a second dielectric layer stack structure sandwiched between said surface of said semiconductor substrate and said second wordlines, said second dielectric layer stack structure being congruent with said second wordlines and providing a charge storage region to those of said memory cell transistors that run along said first direction.

Providing said dielectric layer stack structures congruent with said wordlines may be realized by patterning said dielectric layer stack using said first and second wordlines as a mask structure, for example. At intersections of said first and second wordlines, said second dielectric layer stack is preferably formed over said first wordlines.

According to one aspect of the invention there is provided a non-volatile memory cell array including a plurality of source/drain regions formed within a semiconductor substrate, said plurality of source/drain regions being arranged along a) first lines running in parallel along a first direction as well as b) second lines running in parallel along a second direction, wherein any two neighboring of said plurality of source/drain regions along said first direction include a first channel region formed therebetween and any two neighboring of said plurality of source/drain regions along said second direction include a second channel region formed therebetween, a dielectric layer stack formed on each of said first and second channel regions as a charge storage region, a plurality of first wordlines running in parallel along said first direction, covering said dielectric layer stack of said second channel regions, thereby providing gate electrodes, a plurality of second wordlines running in parallel along said second direction, covering said dielectric layer stack of said first channel regions, thereby providing gate electrodes, a dielectric material sandwiched between said first and second wordlines at intersections thereof, and a plurality of bitlines running in parallel along a third direction, said plurality of bitlines being in electrical contact with said plurality of source/drain regions.

Two neighboring of said plurality of source/drain regions along said first direction including said first channel region formed therebetween constitute part of a memory cell transistor arranged along said first direction. Likewise, two neighboring of said plurality of source/drain regions along said second direction including said second channel region formed therebetween constitute part of a memory cell transistor arranged along said second direction. It is to be noted that each source/drain region may be shared by four memory cell transistors, that is two neighboring memory cell transistors arranged along said first direction and two neighboring memory cell transistors arranged along said second direction. Thus, a very compact memory cell design allowing for an increased storage density may be provided.

According to a one embodiment, said dielectric layer stacks formed on said first channel regions constitute a part of a first dielectric layer stack structure sandwiched between said semiconductor substrate and said first wordlines, said first dielectric layer stack structure being congruent with said first wordlines, and wherein each of said dielectric layer stacks formed on said second channel regions constitute part of a second dielectric layer stack structure sandwiched between said semiconductor substrate and said second wordlines, said second dielectric layer stack structure being congruent with said second wordlines.

Forming said dielectric layer stack structures congruent with said wordlines may be provided by using said wordlines as a mask when patterning said dielectric layer stack structures, for example. It is to be noted that merely those parts of said dielectric layer stack structure covering said first or second channel regions constitute charge storage regions of respective memory cell transistors.

According to one embodiment, a plurality of insulating regions is formed within said semiconductor substrate congruent with said intersections. Thus, said insulating regions are formed below cross-points of first and second wordlines, respectively. Said insulating regions may isolate neighboring channel regions from each other, for example, first channel regions lying next to each other in said second direction as well as second channel regions lying next to each other in said first direction.

In one case, said non-volatile memory cell array comprises at least one of the group of shallow trench isolation, LOCOS and deep trench isolation as said insulating regions. An oxide of silicon may be used as a material for said insulating regions, for example. However further insulating materials may be used and appropriately chosen by the skilled person.

According to one embodiment, said semiconductor substrate includes recess regions at positions of said first channel regions, said first channel regions being arranged deeper inside said semiconductor substrate compared to said second channel regions. Thus, said first channel regions lie below said second channel regions. Such recess regions are formed if said insulating regions are firstly formed as parallel lines along said second direction followed by a self-aligned patterning step removing part of said insulating regions and maintaining said insulating regions at positions corresponding to later intersections of first and second wordlines. Patterning may be carried out as an etch process, for example. Said recess regions in one case include a depth corresponding to the depth of said insulating regions.

In one case, said first and second dielectric layer stack structures include an ONO-stack. Thus, favourable non-volatile memory cells may be provided, e.g., NROM memory cells.

In one case, said first and second directions are perpendicular to each other, said third direction being inclined to said first and second directions by an angle of 45°. Said first, second and third directions are in one case parallel to a surface of said semiconductor substrate. Said third direction constitutes a diagonal of said first and second directions. It is to be noted that said first, second and third directions may be aligned relative to each other in many other ways. Although in one case first and second wordlines and said bitlines are formed as straight lines, it is also possible to form one or more of said first and second wordlines and said bitlines in the form of line formations such as meanders or wavelike lines, for example.

In one case, said non-volatile memory cell array comprises NROM memory cells. Thus, it is possible to store two bits per channel region. As a single memory unit cell according to one embodiment of the present invention, includes two channel regions, namely a first channel region of a first memory cell transistor arranged along said first direction and a second channel region of a second memory cell transistor arranged along said second direction, it becomes possible to store four bits per memory unit cell.

In one case, a width of said first and second wordlines as well as a lateral distance between neighboring first or second wordlines corresponds to a minimum feature size of said non-volatile memory cell array. Denoting said minimum feature size by F, this embodiment allows to provide a 4F² memory unit cell storing four bits per memory unit cell. Two of said four bits may be stored in a memory cell arranged along said first direction and the other two bits may be stored in a memory cell arranged along said second direction, both memory cells sharing one common source/drain region.

According to one aspect of the invention, there is provided a method of forming a non-volatile memory cell array including forming an insulating structure within a semiconductor substrate, said insulating structure including an array of insulating regions, said insulating regions being consecutively arranged along first lines running in parallel along a first direction as well as along second lines running in parallel along a second direction; forming, along said first direction, parallel lines including a first dielectric layer stack over said semiconductor substrate and said insulating regions, a first conductive layer covering said first dielectric layer stack and a first insulating coating structure surrounding said first conductive layer; forming, along said second direction, parallel lines including a second dielectric layer stack over said semiconductor substrate, a second conductive layer covering said second dielectric layer stack and a second insulating coating structure surrounding said second conductive layer, so that intersections of said lines along said first and second directions are congruent with said insulating regions, forming doped semiconductor zones within said semiconductor substrate in regions where said semiconductor substrate is not covered by said first or second dielectric layer stacks; forming contact plugs on said doped semiconductor zones and forming parallel conductive bitlines running along a third direction, said conductive bitlines electrically connecting said contact plugs.

Said doped semiconductor zones are formed laterally in-between neighboring two of said wordlines along said first direction and in-between neighboring two of said wordlines along said second direction. Said insulating coating structures, dielectric layer stacks, insulating regions as well as conductive layers may be defined by lithography and patterning steps, for example.

In one case, said first and second insulating coating structures are formed using insulating spacers. Said insulating spacers may be formed by deposition of an insulating layer followed by a partial back-etch of said insulating layer to leave said insulating spacers behind.

According to one embodiment, said insulating regions are formed of at least one of the group consisting of shallow trench isolation, LOCOS and deep trench isolation. Said insulating regions may be filled with an insulating material such as an oxide of silicon. However, further insulating materials or material combinations may be used and appropriately chosen by the skilled person.

In one case, said insulating structure is initially formed as insulating lines running in parallel along said second direction, and wherein, after providing said lines of said first dielectric layer stack, said insulating regions are formed by removing uncovered parts of said insulating structure, thereby forming recess regions within said semiconductor substrate. Thus, it is possible to provide a self-aligned patterning of said insulating structure in the second direction. Said recess regions are positioned in-between neighboring two of said insulating regions along said second direction and thus correspond to channel regions of memory cell transistors to be formed along said first direction.

In one case, doped semiconductor zones, constituting source/drain regions of said non-volatile memory cell array, are formed by implanting dopants into said semiconductor substrate. These dopants may be implanted self-aligned using said first and second conductive regions as a mask structure, for example.

In one case, said dopants are implanted at a stage where said parallel lines of said second conductive layer are already provided and before said second insulating coating structure is completed. Thus, side-walls of said second conductive layer are not yet covered by insulating spacers when implanting dopants to provide said semiconductor zones.

In one case, said insulating coating structures are formed of nitride.

In one case, a material of said insulating regions is chosen as an oxide of silicon.

In one case, said first and second conductive regions, constituting first and second wordlines, are formed of doped polycrystalline silicon.

According to one embodiment, said first and second dielectric layer stacks are formed as ONO layer stacks constituting charge storage regions of said non-volatile memory cell array. Thus, NROM memory cells may be provided allowing for a favourable storage capacity of two bits per memory cell transistor. As the present embodiment provides two channel regions per memory unit cell it is possible to store four bits per memory unit cell allowing for a significant increase of the charge storage capacity.

According to one embodiment, said first and second wordlines are electrically isolated from each other. The first and second wordlines may also be independently addressed. The bitlines may be formed of metal. The first and second channel regions may include a minimum feature size of the fabrication technology, respectively. Furthermore, the first and second channel regions may be covered in self-aligned, complete and defined way by a control gate, for example the conductive layer. The insulating regions may be formed in self-aligned, rectangular shape, providing a defined isolation between neighboring channel regions. The first and second wordlines may include the minimum feature size of the fabrication technology, respectively, and a pitch between neighboring wordlines may also correspond to the minimum feature size.

The abovementioned features and embodiments may be combined in any way.

In the following reference is again taken to the Figures.

Functionally or structurally similar, comparable or equivalent structures are designated by the same reference symbols below without a detailed description being repeated each time they occur.

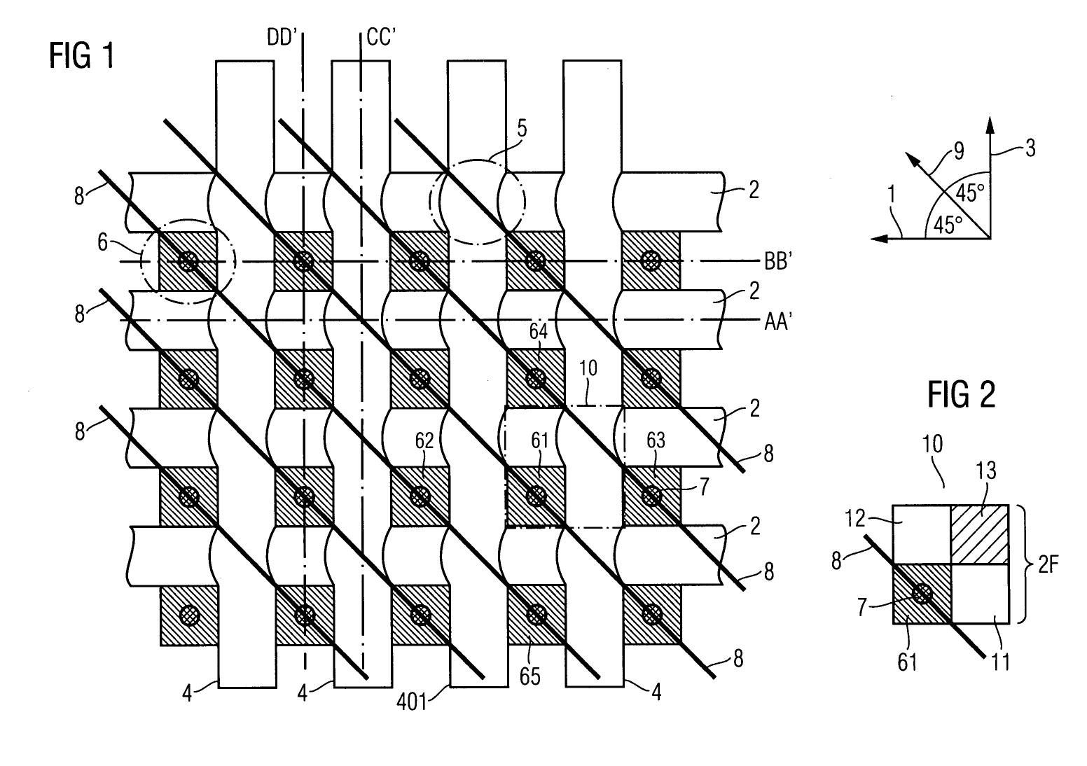

FIG. 1 illustrates a schematic top view of a non-volatile memory cell array according to one embodiment of the invention.

With reference to FIG. 1, the non-volatile memory cell array includes, along a first direction 1, a plurality of first wordlines 2 running in parallel along said first direction 1. There is furthermore provided, along a second direction 3, said second direction 3 lying perpendicular to said first direction 1, a plurality of second wordlines 4 running in parallel along said second direction 3. Said first and second wordlines 2, 4 cross each other at intersections 5. Said first and second wordlines 2, 4 are insulated from each other at said intersections 5 by a dielectric material sandwiched therebetween. In-between neighboring two of said first wordlines 2 and in-between neighboring two of said second wordlines 4, there are provided source/drain regions 6 formed within a semiconductor substrate (not shown). Said source/drain regions 6 are electrically connected, by means of contact plugs 7, to a plurality of bitlines 8 running in parallel along a third direction 9. Said third direction is inclined to said first and second directions 1, 3 by an angle of 45°, respectively, thereby forming a diagonal with respect to said first and second directions 1, 3. It is to be noted that the angles of inclination between said first, second and third directions 1, 3, 9 may also differ from what is shown in FIG. 1. Furthermore, said first and second wordlines 2, 4 as well as said bitlines 8 may be formed as straight lines or further line formations such as meanders or wavelike lines, for example.

Furthermore, a memory unit cell is denoted by reference symbol 10.

For further elucidation of said non-volatile memory cell array attention is drawn to an arbitrary source/drain region 61. Said source/drain region 61 constitutes a source/drain region that is shared by four memory cell transistors. These four memory cell transistors are arranged as follows. A first memory cell transistor is formed by said source/drain region 61 and a further source/drain region 62 arranged to the left along said first direction 1. A channel region of said memory cell transistor arranged along said first direction 1 is formed in-between said source/drain regions 61, 62 (not shown, lying below the respective second wordline). A gate electrode to said memory cell transistor is provided by the one of the second wordlines 4 that runs along said second direction 3 above the respective channel region. In the present example, this respective second wordline is denoted by reference number 401. A second memory cell transistor arranged along said first direction 1 is formed by said source/drain region 61 and a source/drain region 63 also positioned next to said source/drain region 61 with regard to said first direction 1. Furthermore, said source/drain region 61 constitute part of a third memory cell transistor formed along said second direction 3. This further memory cell transistor includes said source/drain region 61 and a source/drain region 64 positioned next to said source/drain region 61 along said second direction 3. Furthermore, said source/drain region 61 constitutes part of yet a fourth memory cell transistor arranged along said second direction 3, said fourth memory cell transistor including said source/drain region 61 and a source/drain region 65 positioned next to said source/drain region 61 along said second direction 3. Regarding memory cell transistors arranged along said second direction 3, a gate electrode is provided by respective first wordlines 2 running along said first direction 1. Each of said memory cells may be accessed via two neighboring of said bitlines 8 as well as one of said first or second wordlines 2, 4.

The top view in FIG. 1 also designates cut lines AA′, BB′, CC′ and DD′. With the help of these cut lines schematic cross-sectional views are designated in order to further elucidate embodiments of the invention.

Reference is now taken to FIG. 2 showing a schematic top view of memory unit cell 10. Said memory unit cell 10, as an example, includes said source/drain region 61 as well as a first channel region 11 constituting part of a memory cell transistor arranged along said first direction 1, namely memory cell transistor including said source/drain region 61, said first channel region 11 and said source/drain region 63 (see FIG. 1). Said memory unit cell 10 further includes a second channel region 12, said second channel region 12 constituting part of a memory cell transistor arranged along said second direction 3, namely a memory cell transistor including said source/drain region 61, said second channel region 12 and said source/drain region 64 (see FIG. 1). Said memory unit cell 10 further includes an insulating region 13. Referring again to FIG. 1, said insulating regions 13 lie below said intersections 5 within said semiconductor substrate (not shown). Said insulating region 13 may be formed by one of the group of shallow trench isolation, LOCOS and deep trench isolation, for example. Said insulating region 13 provides an electrical isolation between neighboring channel regions. Again, said source/drain region 61 is connected to one of said bitlines 8 by one of said contact plugs 7. It is to be noted that charge storage regions are formed above said first and second channel regions 11, 12 (not shown). In case said non-volatile memory cell array includes NROM (nitrided-read-only-memory memory) cells, two bits may be stored per memory cell transistor. As each memory unit cell 10 includes two channel regions, namely the first and second channel regions 11, 12 in the present example, each memory unit cell 10 may be used to store four bits. In case said first and second channel regions 11, 12, said insulating region 13 as well as said exemplary source/drain region 61 may be formed with dimensions corresponding to a minimum feature size F, said memory unit cell 10 comprises dimensions of 2F along said first direction as well as 2F along said second direction, thereby providing a memory unit cell of 4F².

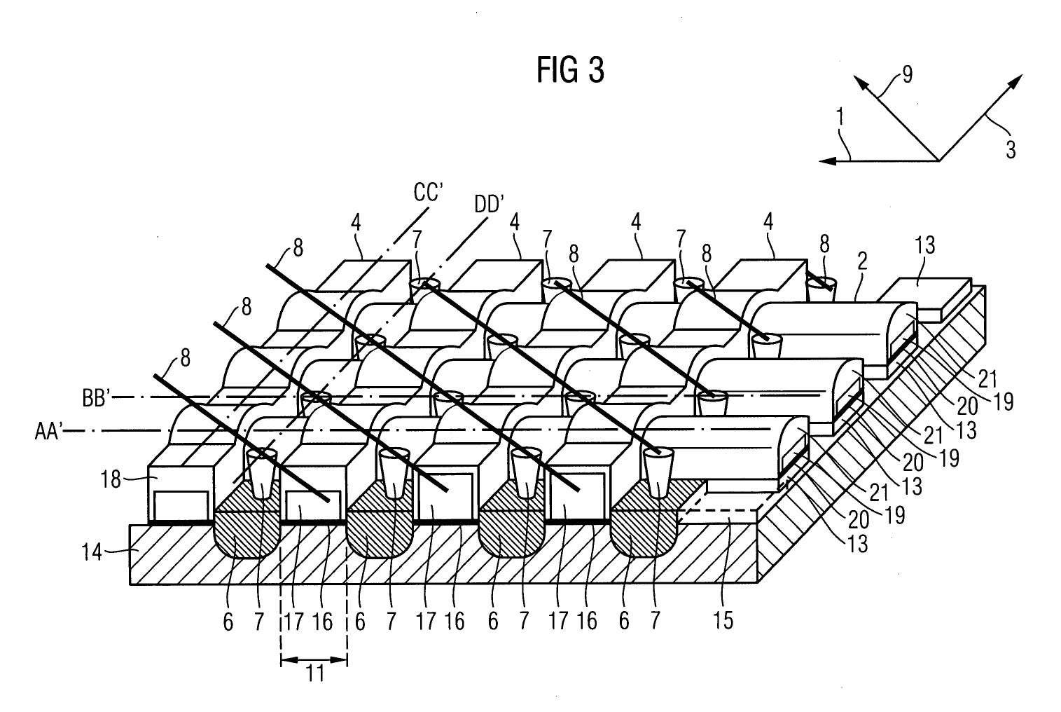

Reference is now taken to FIG. 3 showing a schematic side view of the embodiment shown in FIG. 1.

The source/drain regions 6 are formed within a semiconductor substrate 14. The source/drain regions 6 may be provided as doped semiconductor zones, for example. In-between neighboring two of said source/drain regions 6 positioned along said first direction 1, there is provided said first channel region 11. It is to be noted that recess regions 15 are formed within said semiconductor substrate 14 at positions congruent with said first channel regions 11. (Note that the wordline 4 is omitted in the right part of FIG. 3 to increase intelligibility). These recess regions 15 are caused by a self-aligned patterning step defining said insulating regions 13. In case said insulating regions 13 are formed by merely a single patterning step, e.g., before forming said first and second wordlines 2, 4, said recess regions 15 may also be avoided.

In the present embodiment, below said recess regions 15 there are provided said first channel regions 11 in surface regions of said semiconductor substrate 14. Each memory cell transistor arranged along said first direction 1 further includes a second dielectric layer stack 16 positioned above said first channel region 11. Said second dielectric layer stack 16 may be provided as parallel lines along said second direction 3. Above said second dielectric layer stack 16 there is provided a second conductive layer 17 constituting part of said second wordlines 4. Said second conductive layer 17 provides a gate electrode of memory cell transistors arranged along said first direction 1. By addressing a memory cell via two neighboring source/drain regions 6 arranged along said first direction and the one of said second wordlines 4 that is positioned above a respective first channel region 11, charge may be stored in or erased from the respective part of the second dielectric layer stack 16 that serves as a charge storage region. Thereby, information may be written into or read out from a respective non-volatile memory cell arranged along said first direction 1.

Again, said source/drain regions 6 are connected to respective bitlines 8 via contact plugs 7. A second insulating coating structure 18 is formed surrounding said second conductive layer 17. Said second insulating coating structure 18 may include an insulating material, e.g., a nitride. However, further insulating materials may be used. Likewise, said first wordlines 2 also include a first conductive layer 19 providing a gate electrode for memory cell transistors arranged along said second direction 3. First dielectric layer stacks 20 are sandwiched between said first conductive layers 19 and said semiconductor substrate 14 (i.e., said second channel regions 12 (not shown in FIG. 3) and said insulating regions 13) providing respective charge storage regions of memory cell transistors arranged along said second direction 3. Again, a first insulating coating structure 21 is surrounding said first conductive layers 19, respectively.

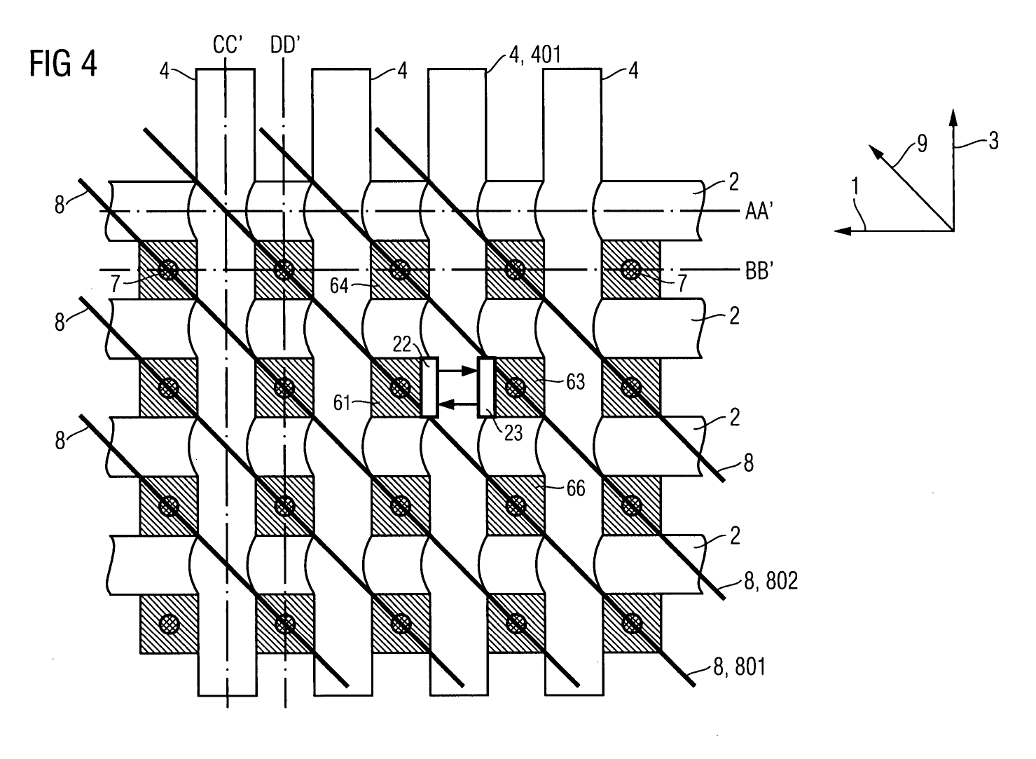

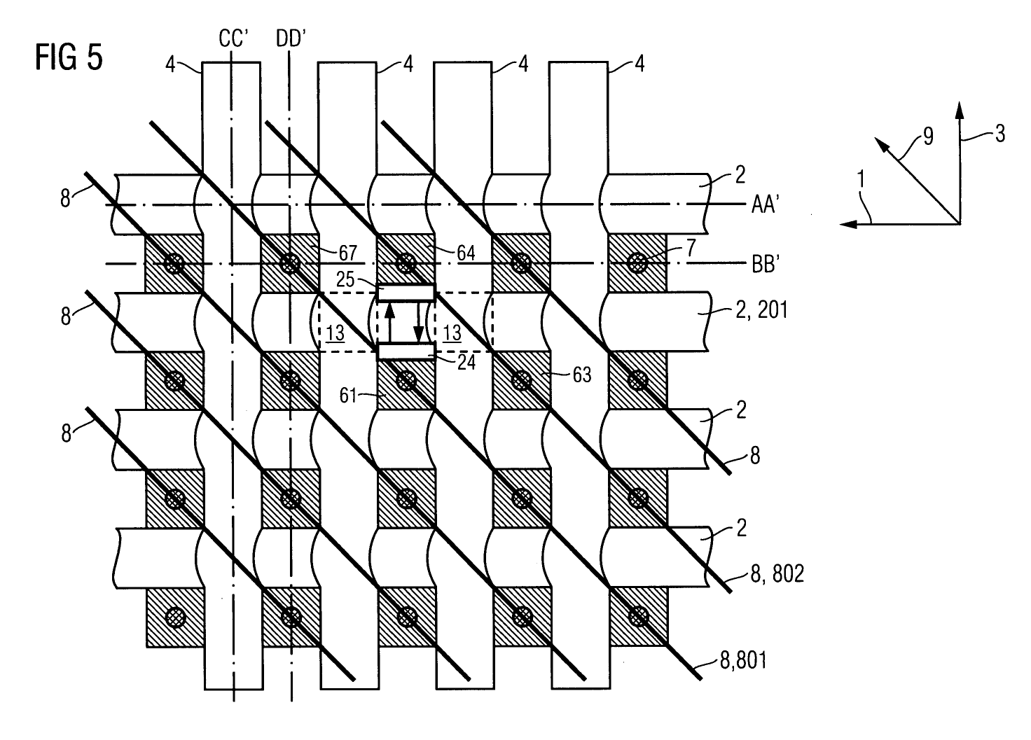

Reference is now taken to FIG. 4 elucidating a programming process of a memory cell arranged along said first direction. In this example, said memory cell is identified by said source/drain regions 61, 63, said first channel region 11 (not shown) formed therebetween. Contact to said source/drain regions 61 and 63 is provided by selected bitlines 801 and 802 and respective contact plugs 7. Now, selection of the wordline 401 allows to charge or discharge a charge storage region provided by a respective part of said second dielectric layer stack 16 formed above the first channel region 11 (not shown) of the selected memory cell. In case of the present example, said non-volatile memory cells are formed as NROM memory cells allowing for a storage of two bits per memory cell transistor. Depending up on the relative voltages of the selected bitlines 801, 802 and the selected wordline 401, a storage region of a first bit 22 located near the source/drain region 61 or a storage region of a second bit 23 located near said source/drain region 63 may be used for programming the respective memory cell or reading out therefrom. As the selected bitlines 801 and 802 also address memory cells arranged along said second direction 3, e.g., a memory cell including said source/drain region 61 and said source/drain region 64 as well as a further memory cell including said source/drain region 63 and a source/drain region 66, respective wordlines of these memory cells have to be kept on an appropriate voltage, e.g., inhibit voltage, in order not to alter the information content stored in these memory cells.

Reference is now taken to FIG. 5 elucidating a programming process of a memory cell arranged along said second direction 3. The memory cells addressed in FIGS. 4, 5 may include first and second channels 11, 12 ascribed to a single memory unit cell 10 (see FIG. 2). Thus storage regions of four bits per unit cell are addressed in FIGS. 4, 5. In this example, said memory cell is identified by said source/drain regions 61, 66, said second channel region 12 (not shown) formed therebetween. Contact to said source/drain regions 61 and 64 is provided by selected bitlines 801 and 802 and respective contact plugs 7. Selection of the wordline 201 allows to charge or discharge a charge storage region provided by a respective part of said first dielectric layer stack 20 formed above the respective first channel region 11 of the selected memory cell. Depending upon the relative voltages of the selected bitlines 801, 802 and the selected wordline 201, a storage region of a third bit 24 located near the source/drain region 61 or a storage region of a fourth bit 23 located near said source/drain region 64 may be addressed for writing or reading. As the selected bitlines 801 and 802 also address memory cells arranged along said first direction 1, namely a memory cell including said source/drain region 61 and said source/drain region 63 as well as a further memory cell including said source/drain region 64 and a source/drain region 67, respective wordlines of these memory cells have to be kept at an appropriate voltage, e.g., inhibit voltage, in order not to alter the information content stored in these memory cells.

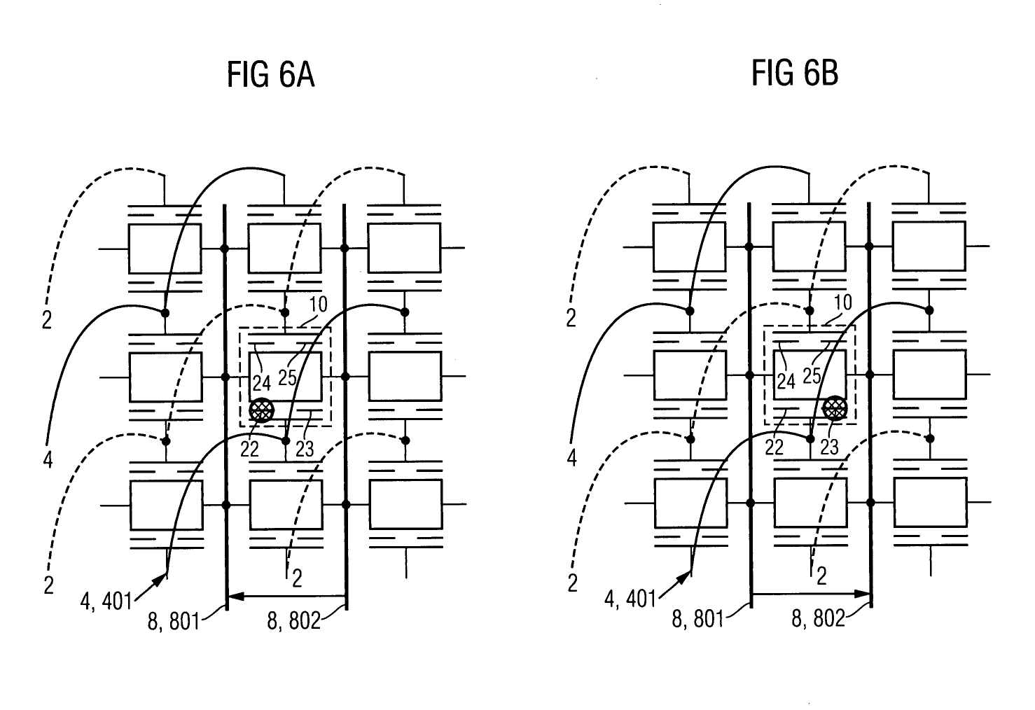

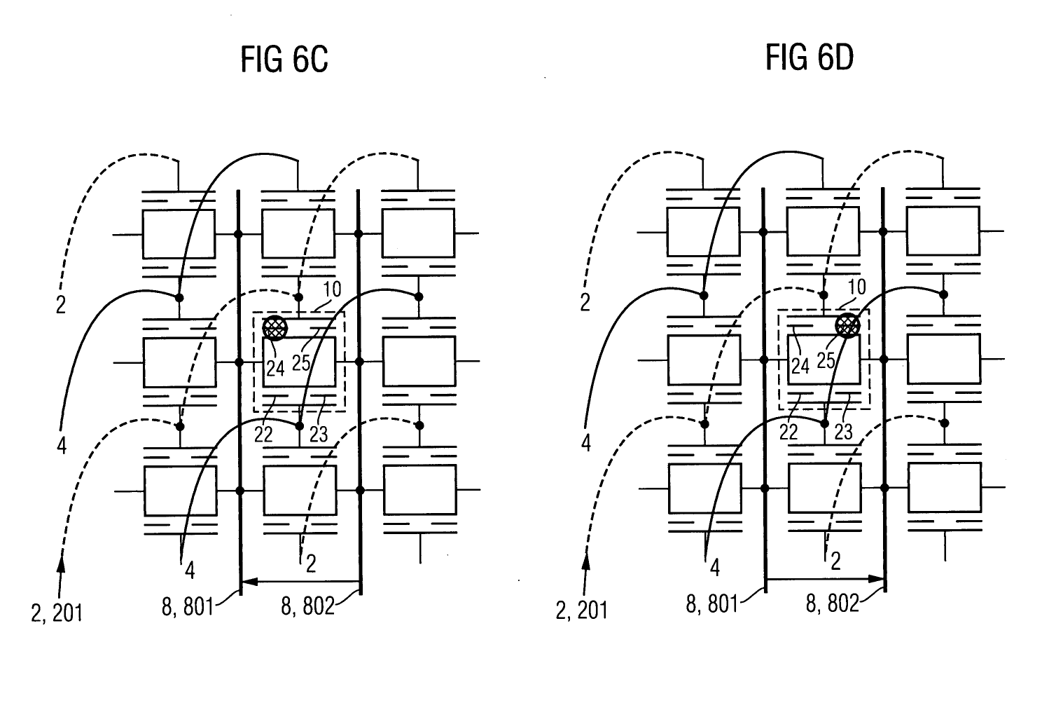

Reference is now taken to FIGS. 6A to 6D showing a simplified structure of an embodiment of a non-volatile memory cell array according to one embodiment of the invention. It is to be noted that the program operations elucidated in FIGS. 6A, 6B give an alternative illustration of the programming process described with respect to FIG. 4. Likewise, FIGS. 6C, 6D give an alternative illustration of the programming process described with respect to FIG. 5. Thus, these Figures may also be taken into account to encourage understanding of the details below.

Starting with FIG. 6A, the memory unit cell 10 is addressed via the selected second wordline 401 and the selected bitlines 801 and 802 (see FIG. 4). A forward programming cycle to address the storage region of said first bit 22 may be carried out by applying a first voltage to said selected bitline 801 and a second voltage to said selected bitline 802.

Continuing with FIG. 6B, the memory unit cell 10 is again addressed via the second wordline 401 and the selected bitlines 801 and 802 (see FIG. 4). A reverse programming cycle to address the storage region of said second bit 23 may be carried out by applying the second voltage to said selected bitline 801 and the first voltage to said selected bitline 802.

Continuing with FIG. 6C, the memory unit cell 10 is now addressed via the selected first wordline 201 and the selected bitlines 801 and 802 (see FIG. 5). A forward programming cycle to address said storage region of the third bit 24 may be carried out by applying the first voltage to said selected bitline 801 and the second voltage to said selected bitline 802.

Continuing with FIG. 6D, the memory unit cell 10 is again addressed via the first wordline 201 and the selected bitlines 801 and 802 (see FIG. 5). A reverse programming cycle to address said storage region of the fourth bit 25 may be carried out by applying the second voltage to said selected bitline 801 and the first voltage to said selected bitline 802.

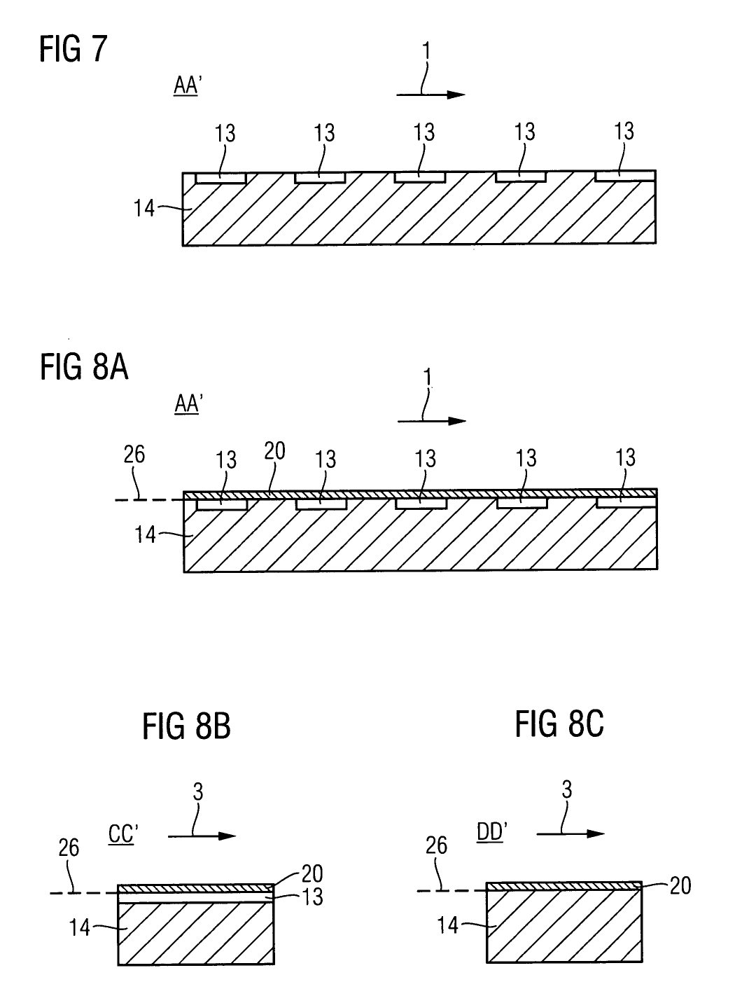

Reference is now taken to FIGS. 7 to 19 elucidating subsequent process steps of a method of forming a non-volatile memory cell array according to an embodiment of the invention. The process steps to be further described herein refer to the embodiment shown in FIGS. 1 and 3. The subsequent process steps are elucidated with respect to schematic cross-sectional views at different stages of fabrication. These cross-sectional views are linked to the non-volatile memory cell array to be fabricated at positions identified by the respective cut lines of FIGS. 1 and 3.

Referring to FIG. 7, there is shown a cross-sectional view of the array to be fabricated along the cut line AA′ (see FIGS. 1, 3) at the beginning of the fabrication process. Within said semiconductor substrate 14 insulating regions 13 are formed. Said semiconductor substrate 14 may be of silicon, for example. Said insulating regions 13 may be formed as shallow trench isolation regions including an oxide of silicon as an insulating material. However, these material choices as well as further material choices given below are merely descriptive and not restrictive at all.

In a subsequent process step, shown in FIG. 8A as a cross-sectional view along the cut line AA′, said first dielectric layer stack 20 is formed over a surface 26 of said semiconductor substrate 14.

Referring to FIG. 8B, there is shown a cross-sectional view along the cut line CC′. As can be gathered from FIG. 8B the insulating regions 13 are formed as parallel lines running along said second direction 3.

Referring to FIG. 8C there is shown a cross-sectional view along the cut line DD′. Here, said insulating regions 13 are not present and said first dielectric layer stack 20 is directly formed on said semiconductor substrate 14. The first dielectric layer stack 20 provides a charge storage region of memory cells to be formed along said second direction 3.

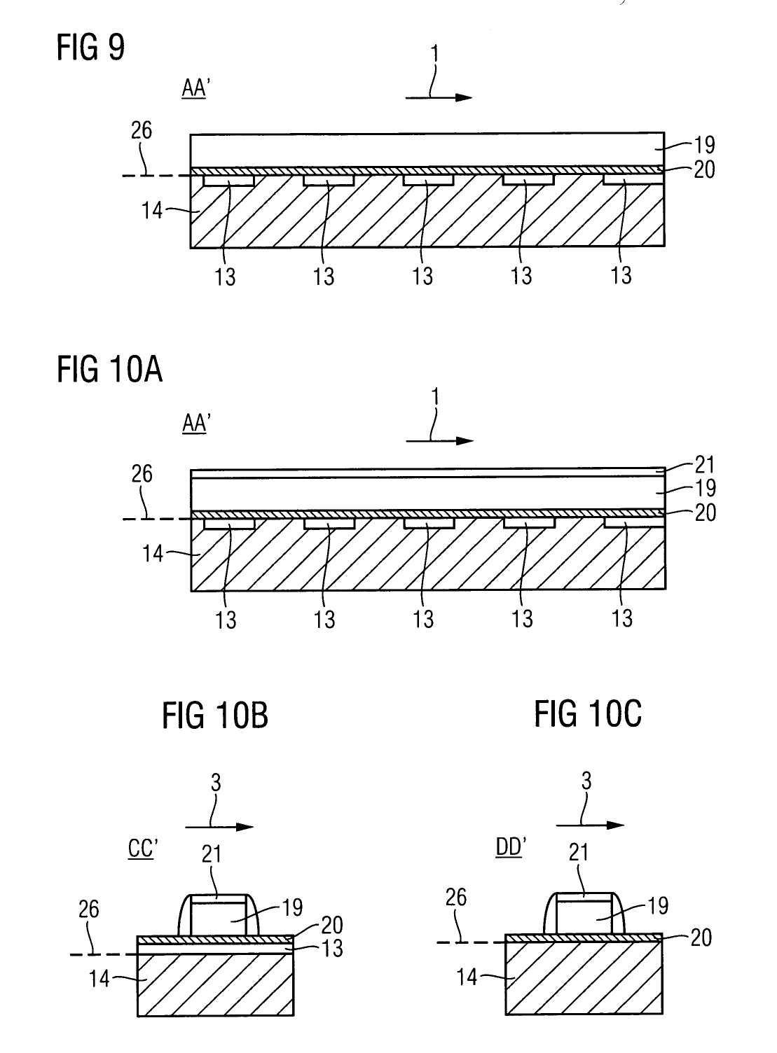

Reference is now taken to FIG. 9 showing a cross-sectional view along the cut line AA′ after formation of said first conductive layer 19. Said first conductive layer 19 may be formed of doped silicon, for example, and provides a gate electrode of memory cells to be formed along said second direction 3.

Reference is now taken to FIG. 10A showing a cross-sectional view along the cut line AA′ after formation of a first insulating coating structure 21 over said first conductive layer 19. Said first insulating coating structure 21 may include nitride, for example.

Reference is now taken to FIG. 10B showing a cross-sectional view along the cut line CC′. As can be gathered from this Figure, the first conductive layer 19 as well as the first insulating coating structure 21 surrounding said first conductive layer 20 are patterned in the form of lines running in parallel along said first direction 1. Formation of said first insulating structure 21 may includes several deposition and patterning steps, for example. It is furthermore possible to use a common patterning step for definition of the first conductive layer 19 as well as at least part of said first insulating coating structure 21.

Reference is now taken to FIG. 10C showing a schematic cross-sectional view along the cut line DD′. Contrary to the view of FIG. 10B, the first dielectric layer stack 20 is directly formed over said semiconductor surface. The cross-sectional view of FIG. 10C thus provides a cross-sectional view of a memory cell transistor to be formed along said second direction 3 (Source/drain regions not yet processed).

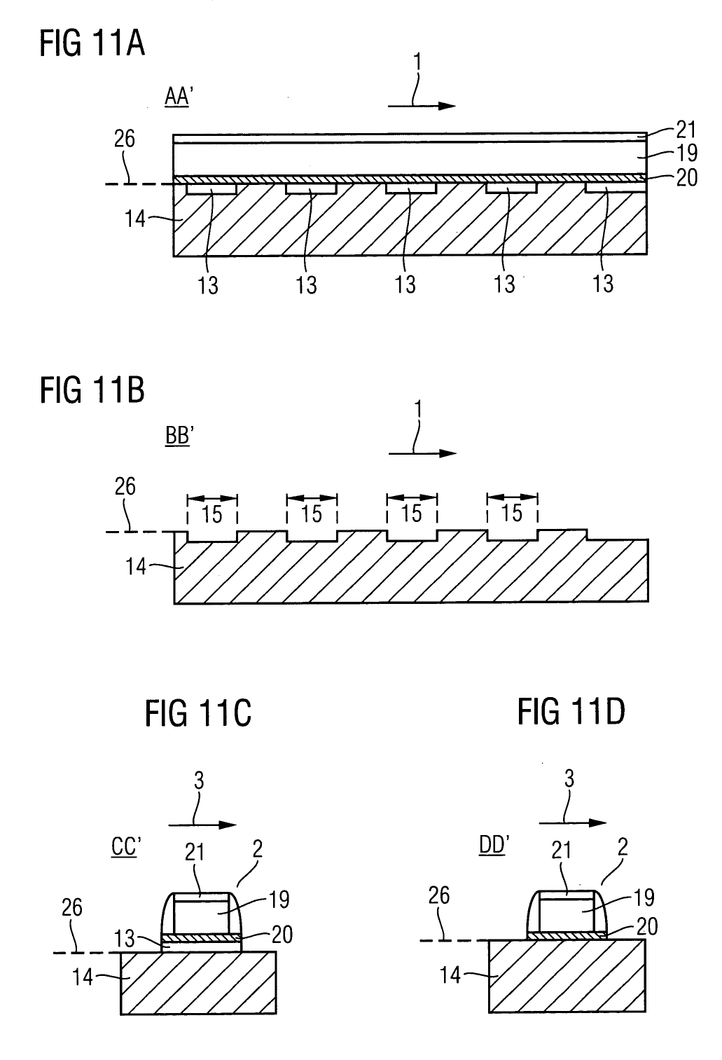

Reference is now taken to FIG. 11A showing a cross-sectional view along the cut line AA′ after patterning said first dielectric layer stack 20 and said insulating regions 13. This patterning step is self-aligned with respect to said first wordline 4 including said first conductive layer 19 and said first insulating coating structure 21. Thus, partial removal of said first dielectric layer stack 20 and said insulating regions 13 are merely effective with regard to a cross-sectional view along the cut line BB′ (not apparent from FIG. 11A).

Such a cross-sectional view along the cut line BB′ after patterning said first dielectric layer stack 20 and said insulating regions 13 is shown in FIG. 11B. Here, the surface 26 of said semiconductor substrate 14 is exposed for further definition of memory cells arranged along said second direction 3. Also provided are recess regions 15 that arise due to partial removal of said insulating regions 13. Patterning said insulating regions 13, first dielectric layer stack 20, first conductive layer 19 and first insulating coating structure 21 may be carried out by appropriate etch processes, for example.

Reference is now taken to FIG. 11C showing a cross-sectional view along the cut line CC′. This cross-sectional view refers to the first wordlines 2 running along said first direction 1. Again, the conductive layer 19 is surrounded by said first insulating coating structure 21 and formed over said first dielectric layer stack 20. However, the part of the dielectric layer stack 20 shown here does not constitute a charge storage region of a memory cell as the insulating region 13 is sandwiched between the first dielectric layer stack 20 and the semiconductor substrate 14.

Reference is now taken to FIG. 11D showing a cross-sectional view along the cut line DD′. Contrary to FIG. 11C, the first dielectric layer stack 20 is directly formed on said semiconductor substrate 14. Thus, said dielectric layer stack 20 forms a charge storage region in this part of the wordline 2.

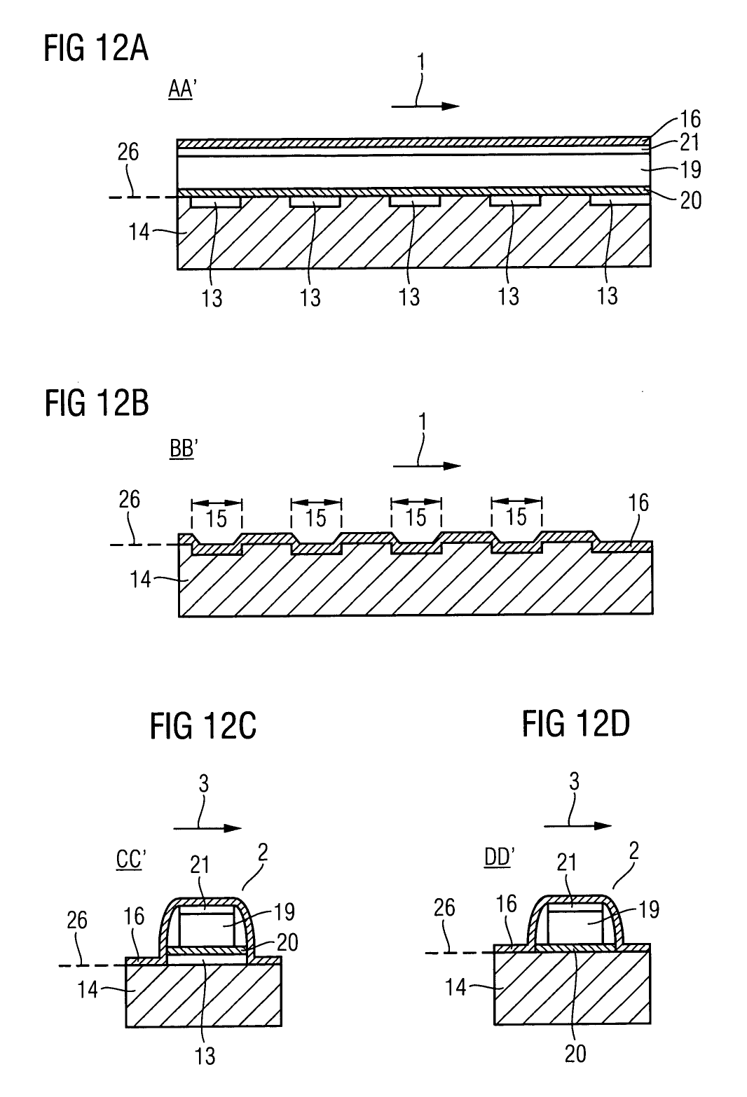

Reference is now taken to FIG. 12A showing a cross-sectional view along the cut line AA′ after formation of the second dielectric layer stack 16. Said second dielectric layer stack 16 is provided for realizing charge storage regions of memory cell transistors arranged along said first direction 1.

Reference is now taken to FIG. 12B showing a cross-sectional view along the cut line BB′. Here, the second dielectric layer stack 16 is directly formed over said semiconductor substrate 14. It is to be noted that merely those parts of the second dielectric layer stack 16 that are positioned within the recess regions 15 constitute charge storage regions of respective memory cells to be formed along said first direction 1.

Reference is now taken to FIG. 12C showing a cross-sectional view along the cut line CC′. Compared to FIG. 11C, there is provided the second dielectric layer stack 16 formed over the semiconductor substrate 14 as well as the first wordlines 2.

Reference is now taken to FIG. 12D showing a cross-sectional view along the cut line DD′. Compared to FIG. 11D there is provided the second dielectric layer stack 16 formed over said semiconductor substrate 14 as well as said first wordlines 2.

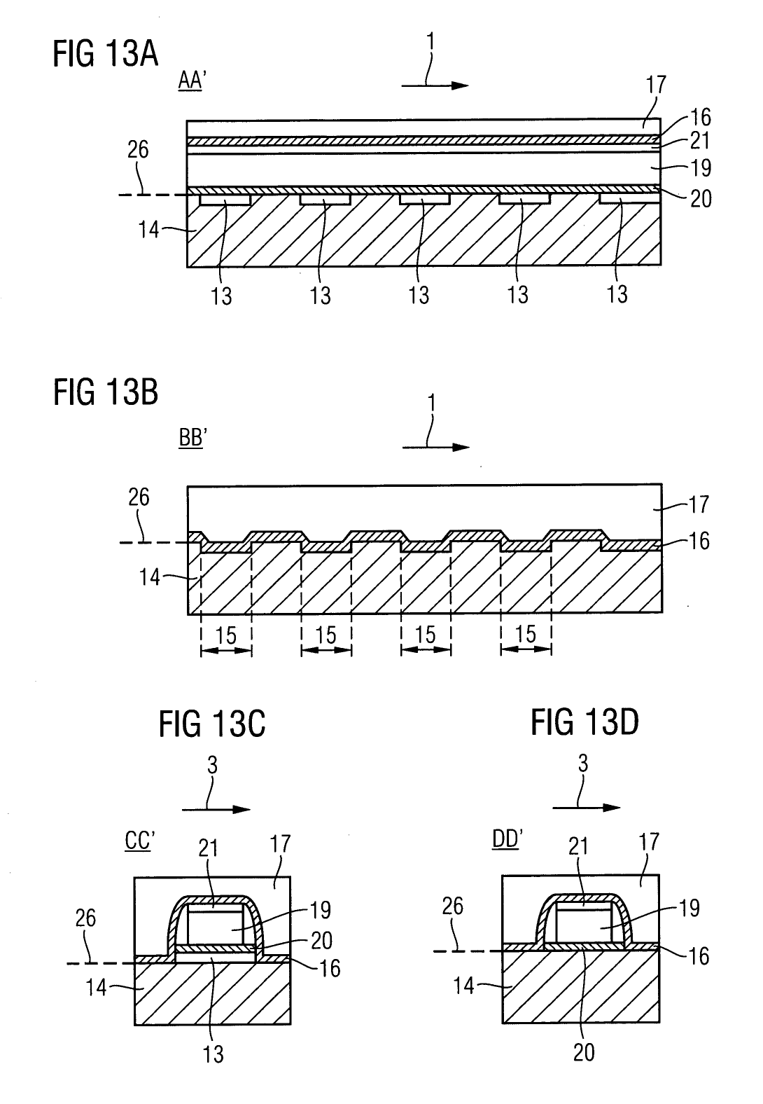

Reference is now taken to FIG. 13A showing a cross-sectional view along the cut line AA′. Here, the second conductive layer 17 is formed over said second dielectric layer stack 16.

As the second dielectric layer stack 16 overlaps first wordlines 2 in this region, intersections 5 will be later defined congruent with said insulating regions 13.

Reference is now taken to FIG. 13B showing a cross-sectional view along the cut line BB′. Again, the second conductive layer 17 is directly formed on said second dielectric layer stack 16. However, said second dielectric layer stack is directly formed on said semiconductor substrate 14. It is to be noted that those parts of the second conductive layer 17 that are arranged above said recess regions 15 will later provide gate electrodes of respective memory cell transistors to be formed along said first direction 1.

Reference is now taken to FIG. 13C showing a cross-sectional view along the cut line CC′. In addition to what is shown in FIG. 12C the second conductive layer 17 is formed over said second dielectric layer stack 16.

Reference is now taken to FIG. 13D showing a cross-sectional view along the cut line DD′. In addition to what is shown in FIG. 12D, the second conductive layer 17 is provided above said second dielectric layer stack 16.

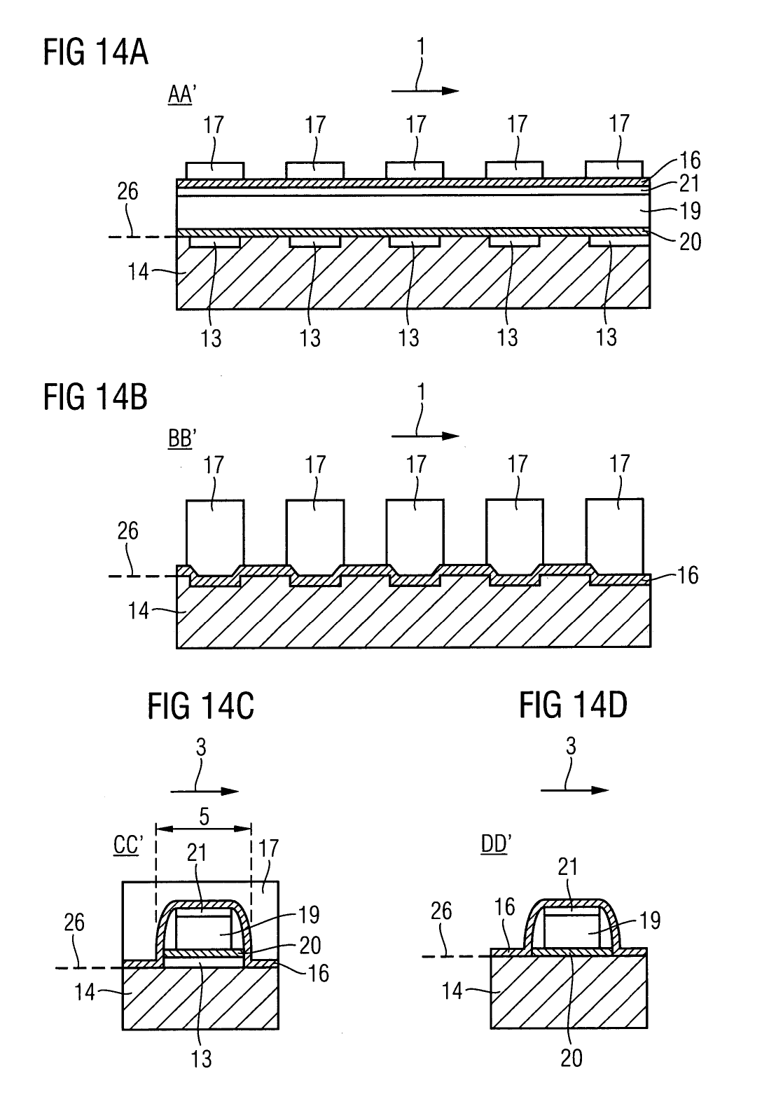

In FIG. 14A there is shown a cross-sectional view along the cut line AA′ after patterning said second conductive layer 17 in parallel lines running along said second direction 3.

With regard to FIG. 14B there is shown a cross-sectional view along the cut line BB′. Here, the second conductive layer is formed over those parts of the second dielectric layer stack 16 that are formed within the recess regions 15, said respective parts of the second dielectric layer stack 16 providing charge storage regions of memory cells arranged along said first direction 1.

Reference is now taken to FIG. 14C showing a cross-sectional view along the cut line CC′. It is to be noted that the intersections 5 constituting cross-points of first and second conductive layers 19, 17, i.e., first and second wordlines 2, 4 are positioned congruent with said insulating regions 13.

Reference is now taken to FIG. 14D showing a cross-sectional view along the cut line DD′. Here, the second conductive layer 17 is removed. Again, this cross-sectional view refers to a memory cell transistor to be formed along said second direction 3 (source/drain regions to be defined).

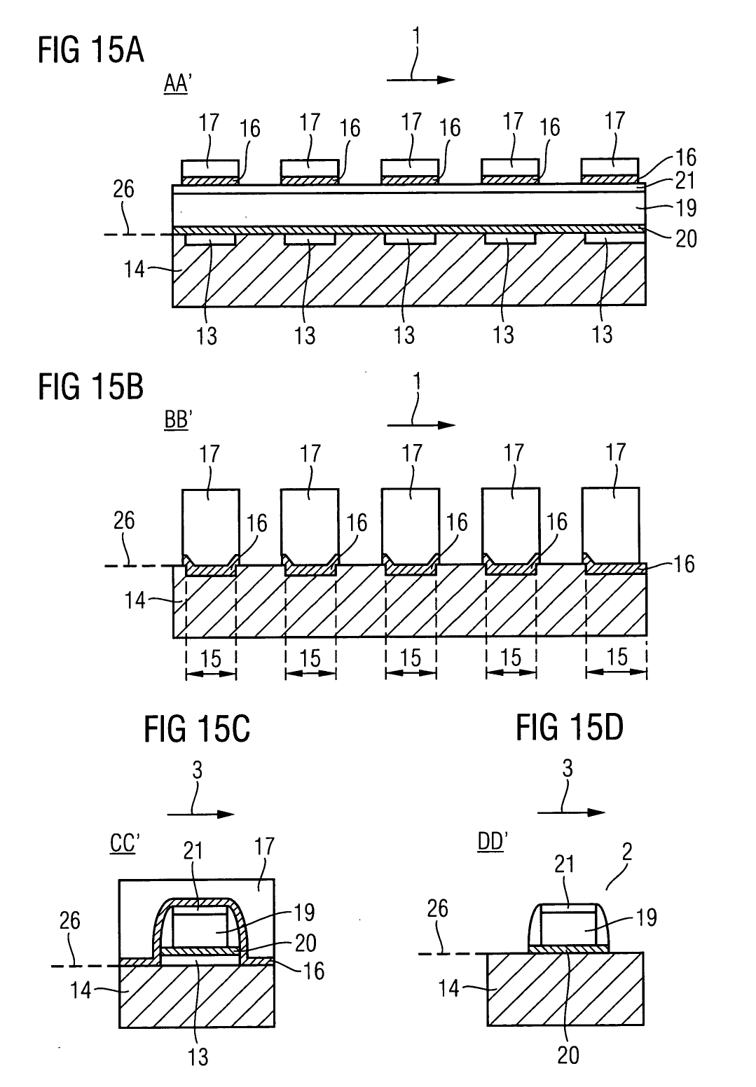

Reference is now taken to FIG. 15A showing a cross-sectional view along the cut line AA′ after patterning said second dielectric layer stack 16. Here, said dielectric layer stack 16 is patterned using said second conductive layer 19 as a mask. Thus, said second dielectric layer stack 16 is formed congruent with said second conductive layer 17.

Reference is now taken to FIG. 15B showing a cross-sectional view along the cut line BB′. Here, the second dielectric layer stack 16 is directly formed on said semiconductor substrate within said recess regions 15 providing a charge storage region for memory cells arranged along said first direction 1. Furthermore, the second conductive layer 17 provides gate electrodes to memory cell transistors to be formed along said first direction 1.

Reference is now taken to FIG. 15C showing a cross-sectional view along the cut line CC′. As the second dielectric layer stack 16 is merely removed in regions not covered by said second conductive layer 17, said cross-sectional view corresponds to the one shown in FIG. 14C.

Reference is now taken to FIG. 15D showing a cross-sectional view along the cut line DD′. In addition to the cross-sectional view shown in FIG. 14D, said second dielectric layer stack 16 is removed in this part of the memory cell array.

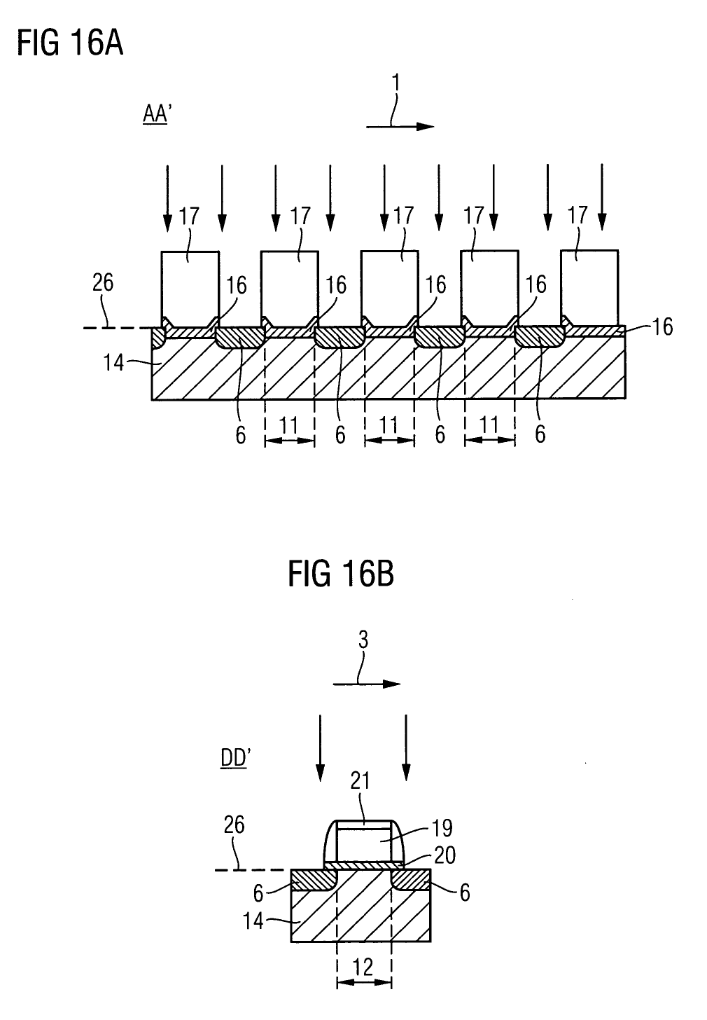

Reference is now taken to FIG. 16A showing a cross-sectional view along the cut line AA′. Due to the partial removal of said second dielectric layer stack 16 part of said semiconductor substrate 14 is exposed. Using the second conductive layer 17 and the first wordlines 2 as a mask, dopants are implanted into the semiconductor substrate 14 to provide source/drain regions 6 constituting doped semiconductor zones. Two neighboring of said source/drain regions 6 shown in FIG. 16A define a memory cell transistor arranged along said first direction 1, said memory cell transistor including a first channel region 11, said first channel region 11 being formed within said semiconductor substrate 14 below said second dielectric layer stack 16. The second dielectric layer stack 16 in this region serves as a charge storage region accessed by the respective part of the second conductive layer 17 formed thereon.

Reference is now taken to FIG. 16B showing a cross-sectional view along the cut line DD′. Contrary to FIG. 16A there is shown a cross-sectional view of a memory cell transistor arranged along the second direction 3. Here, a respective part of said first dielectric layer stack 20 serves as the charge storage region accessed by a respective part of the first conductive layer 19 that is surrounded by the first insulating coating structure 21. The second channel region 12 is formed in-between neighboring two of said source/drain regions 6 positioned along said second direction 3.

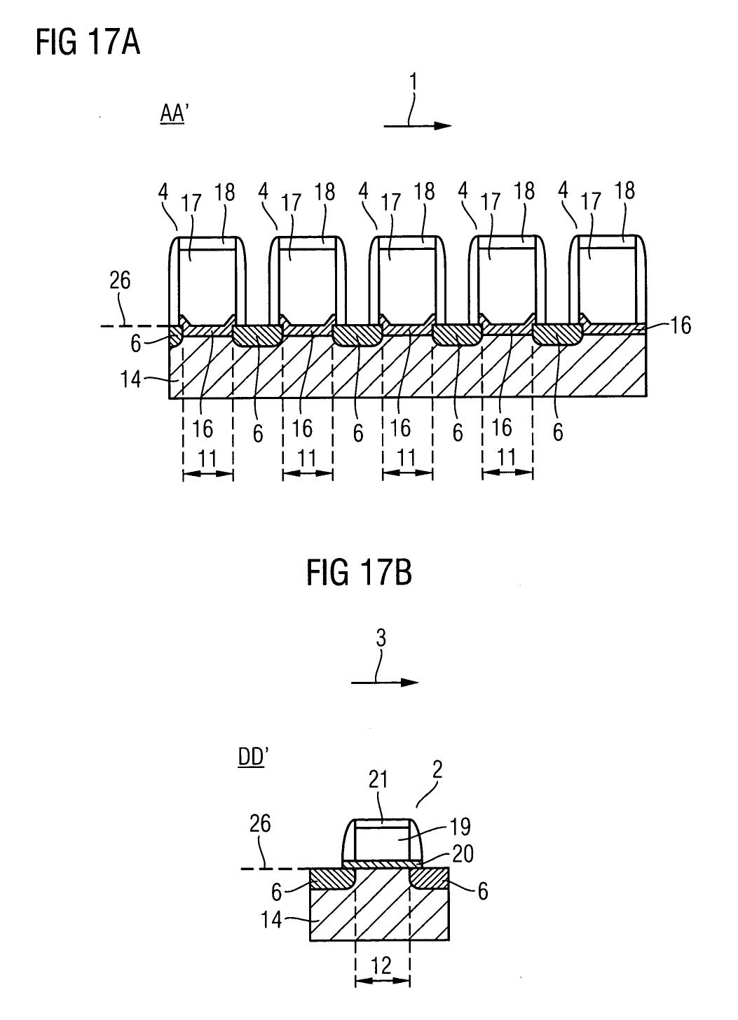

Reference is now taken to FIG. 17A showing a cross-sectional view along the cut line AA′ after formation of the second insulating coating structure 18 surrounding said conductive layer 17. Thus, said second wordlines 4 are completed providing gate electrodes of memory cell transistors arranged along said first direction 1.

Reference is now taken to FIG. 17B showing a cross-sectional view along the cut line DD′. As the formation of the second insulating coating structure 18 merely addresses the second conductive layer 17, the cross-sectional view shown in FIG. 17B corresponds to the one shown in FIG. 16B.

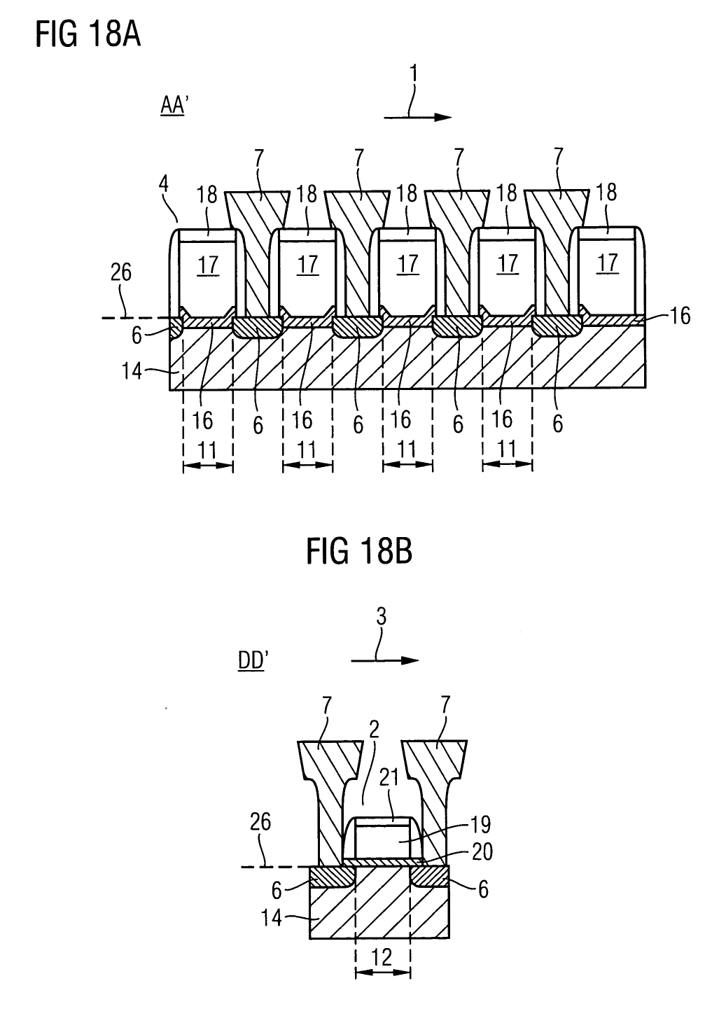

In FIG. 18A there is shown a cross-sectional view along the cut line AA′ after formation of contact plugs 7 contacting said source/drain regions 6. Thus, contact is provided to the memory cell transistors arranged along said first direction 1.

However, said contact plugs 7 also provide contact to memory cell transistors arranged along said second direction 3 as is schematically shown by a cross-sectional view along the cut line DD′ in FIG. 18B. Here, the cross-sectional view refers to a memory cell transistor formed along said second direction 3.

Again, it is noted that said first wordlines 2 provide gate electrodes to said memory cell transistors arranged along the second direction 3 (e.g., FIG. 18B), whereas said second wordlines 2 provide gate electrodes to said memory cell transistors arranged along said first direction 1 (see e.g., FIG. 18A).

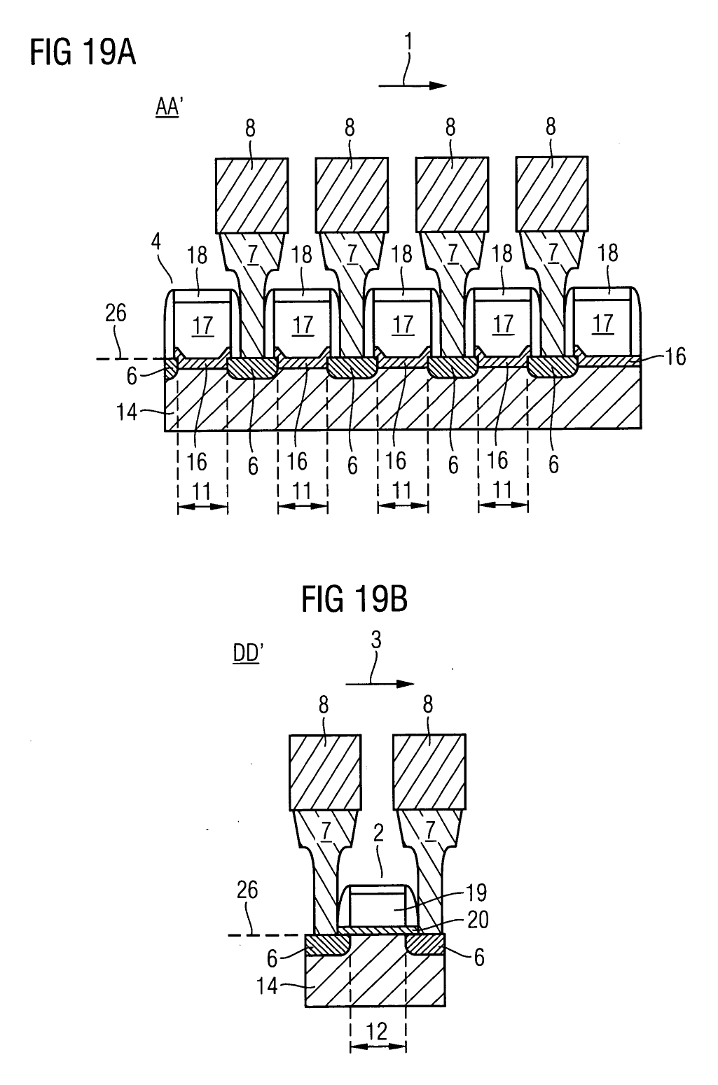

Reference is now taken to FIG. 19A showing a cross-sectional view along the cut line AA′ after formation of said bitlines 8. Said bitlines 8 are formed as lines running in parallel along said third direction (not apparent from FIG. 19A, see e.g., FIG. 1).

In FIG. 19B there is shown a cross-sectional view along the cut line DD′ showing a memory cell transistor arranged along the second direction 3.

As can be gathered from FIGS. 19A and 19B a memory cell, either arranged along the first direction or along the second direction, may be addressed by selecting neighboring two of said bitlines 8 as well as one of said wordlines 2 in case a memory cell arranged along said second direction 3 is to be addressed or one of said wordlines 4 in case a memory cell positioned along said first direction 1 is to be addressed.

It is to be noted, that further insulating layers may be provided in-between neighboring bitlines 8. A description thereof is, however, omitted in order to focus on more relevant aspects of the invention.

Although specific embodiments have been illustrated and described herein, it will be appreciated by those of ordinary skill in the art that a variety of alternate and/or equivalent implementations may be substituted for the specific embodiments shown and described without departing from the spirit and scope of the present invention. This application is intended to cover any adaptions or variations of the specific embodiments discussed herein. Therefore, it is intended that this invention be limited only by the claims and the equivalence thereof.

What is claimed is:

1. A non-volatile memory cell array comprising:
a plurality of memory cell transistors comprising source/drain regions positioned along first lines running in parallel along a first direction and second lines running in parallel along a second direction;
a plurality of first wordlines running in parallel along said first direction, said first wordlines providing gate electrodes to those of said plurality of memory cell transistors that run along said second direction;
a plurality of second wordlines running in parallel along said second direction, said second wordlines providing gate electrodes to those of said plurality of memory cell transistors that run along said first direction, said second wordlines being formed over said first wordlines at intersections thereof;
a dielectric material sandwiched between said first and second wordlines at said intersections; and
a plurality of bitlines running in parallel along a third direction, said plurality of bitlines being in electrical contact with said source/drain regions.

2. A non-volatile memory cell array, comprising
a plurality of memory cell transistors sub-divided in a first part of memory cell transistors and a second part of memory cell transistors, each of said plurality of memory cell transistor comprising source/drain regions;
a plurality of first wordlines running in parallel along a first direction and a plurality of second wordlines running in parallel along a second direction, wherein said first wordlines provide gate electrodes to said first part of memory cell transistors and wherein said second wordlines provide gate electrodes to said second part of memory cell transistors;
a dielectric material sandwiched in-between said first wordlines and said second wordlines at intersections thereof; and
a plurality of bitlines running in parallel along a third direction, said plurality of bitlines being in electrical contact with said source/drain regions.

3. The non-volatile memory cell array of claim 2, wherein said first part of memory cell transistors run along said first direction, and wherein said second part of memory cell transistors run along said second direction.

4. The non-volatile memory cell array of claim 2, further comprising a plurality of insulating regions formed within a semiconductor substrate congruent with said intersections.

5. The non-volatile memory cell array of claim 4, comprising at least one of the group of shallow trench isolation, LOCOS and deep trench isolation as said insulating regions.

6. The non-volatile memory cell array of claim 5, wherein each of said plurality of memory cell transistors comprises two source/drain regions, each of said source/drain regions is shared between neighboring two of said plurality of memory cell transistors running in said first direction as well as between neighboring two of said plurality of memory cell transistors running in said second direction, and each of said source/drain regions is formed within said semiconductor substrate laterally positioned in-between two neighboring of said first wordlines and in-between two neighboring of said second wordlines.

7. The non-volatile memory cell array of claim 6, further comprising:
a first dielectric layer stack structure sandwiched between a surface of said semiconductor substrate and said first wordlines, said first dielectric layer stack structure being congruent with said first wordlines and providing a charge storage region to those of said memory cell transistors that run along said second direction; and
a second dielectric layer stack structure sandwiched between said surface of said semiconductor substrate and said second wordlines, said second dielectric layer stack structure being congruent with said second wordlines and providing a charge storage region to those of said memory cell transistors that run along said first direction.

8. The non-volatile memory cell array of claim 7, wherein said first and second dielectric layer stack structures comprise an ONO-stack.

9. The non-volatile memory cell array of claim 8, wherein said first and second directions are perpendicular to each other, said third directioned being inclined to said first and second directions by an angle of 45′.

10. The non-volatile memory cell array of claim 9, wherein said array comprises NROM memory cells.

11. The non-volatile memory cell array of claim 10, wherein a width of said first and second wordlines as well as a lateral distance between neighboring first or second wordlines correspond to a minimum feature size of said non-volatile memory cell array.

12. A non-volatile memory cell array, comprising:
a plurality of first worldlines running in parallel along a first direction;
a plurality of second wordlines running in parallel along a second direction, said first and second wordlines being isolated from each other at intersections thereof by a dielectric material sandwiched therebetween;
a plurality of source/drain regions;
wherein each one of said plurality of source/drain regions is formed within a semiconductor substrate laterally positioned in-between two neighboring of said first wordlines and in-between two neighboring of said second wordlines;
wherein neighboring two of said plurality of source/drain regions in said first direction define source and drain of a memory cell transistor comprising one of said second wordlines as a gate electrode;
wherein neighboring two of said plurality of source/drain regions in said second direction define source and drain of a memory cell transistor comprising one of said first wordlines as a gate electrode; and
a plurality of bitlines running in parallel along a third direction, said plurality of bitlines providing electrical contact to said plurality of source/drain regions.

13. The non-volatile memory cell array of claim 12, further comprising:
a first dielectric layer stack structure sandwiched between said semiconductor substrate and said first wordlines, said first dielectric layer stack structure being congruent with said first wordlines and providing a charge storage region to those of said memory cell transistors that run along said second direction; and
a second dielectric layer stack structure sandwiched between said surface of said semiconductor substrate and second wordlines, said second dielectric layer stack structure being congruent with said second wordlines and providing a charge storage region to those of said memory cell transistors that run along said first direction.

14. A non-volatile memory cell array comprising:
a plurality of source/drain regions formed within a semiconductor substrate, said plurality of source/drain regions being arranged along a) first lines running in parallel along a first direction as well as b) second lines running in parallel along a second direction, wherein any two neighboring of said plurality of source/drain regions along said first direction comprise a first channel region formed therebetween and any two neighboring of said plurality of source/drain regions along said second direction comprise a second channel region formed therebetween;
a dielectric layer stack formed on each of said first and second channel regions as a charge storage region;
a plurality of first wordlines running in parallel along said first direction, covering said dielectric layer stack of said second channel regions, thereby providing gate electrodes;
a plurality of second wordlines running in parallel along said second direction, covering said dielectric layer stack of said first channel regions, thereby providing gate electrodes;
a dielectric material sandwiched between said first and second wordlines at intersections thereof; and
a plurality of bitlines running in parallel along a third direction, said plurality of bitlines being in electrical contact with said plurality of source/drain regions.

15. The non-volatile memory cell array of claim 14, wherein each of said dielectric layer stacks formed on said first channel regions constitutes part of a first dielectric layer stack structure sandwiched between said semiconductor substrate and said first wordlines, said first dielectric layer stack structure being congruent with said first wordlines and wherein each of said dielectric layer stacks formed on said second channel regions constitutes part of a second dielectric layer stack structure sandwiched between said semiconductor substrate and said second wordlines, said second dielectric layer stack structure being congruent with said second wordlines.

16. The non-volatile memory cell array of claim 14, further comprising a plurality of insulating regions formed within said semiconductor substrate congruent with said intersections.

17. The non-volatile memory cell array of claim 16, comprising at least one of the group of shallow trench isolation, LOCOS and deep trench isolation as said insulating regions.

18. The non-volatile memory cell of claim 17, wherein said semiconductor substrate comprises recess regions at positions of said first channel regions, said first channel regions being arranged deeper inside said semiconductor substrate compared to said second channel regions.

19. The non-volatile memory cell array of claim 18, wherein said recess regions comprise a depth corresponding to a depth of said insulating regions.

20. The non-volatile memory cell array of claim 19, wherein said first and second dielectric layer stack structures comprise an ONO-stack.

21. The non-volatile memory cell array of claim 20, wherein said first and second directions are perpendicular to each other, said third directioned being inclined to said first and second directions by an angle of 45′.

22. The non-volatile memory cell array of claim 21, wherein said array comprises NROM memory cells.

23. The non-volatile memory cell of claim 22, wherein a width of said first and second wordlines as well as a lateral distance between neighboring first or second wordlines corresponds to a minimum feature size of said non-volatile memory cell array.

24. A method of forming a non-volatile memory cell array comprising:
forming an insulating structure within a semiconductor substrate, said insulating structure comprising an array of insulation regions, said insulating regions being consecutively arranged along first lines running in parallel along a first direction as well as along second lines running in parallel along a second direction;
forming, along said first direction, parallel lines comprising a first dielectric layer stack over said semiconductor substrate and said insulating regions, a first conductive layer covering said first dielectric layer stack and a first insulating coating structure surrounding said first conductive layer;
forming, along said second direction, parallel lines comprising a second dielectric layer stack over said semiconductor substrate, a second conductive layer covering said second dielectric layer stack and a second insulating structure surrounding said second conductive layer, so that intersections of said lines along said first and second directions are congruent with said insulating regions;
forming doped semiconductor zones within said semiconductor substrate in regions where said semiconductor substrate is not covered by said first or second dielectric layer stacks;
forming contact plugs onto said doped semiconductor zones; and
forming parallel bitlines running along a third direction, said bitlines electrically contacting said contact plugs.

25. The method of claim 24, wherein said first and second insulating structures are formed using insulating spacers.

26. The method of claim 25, wherein said insulating regions are formed of at least one of the group consisting of shallow trench isolation, LOCOS, deep trench isolation.

27. The method of claim 26, wherein said insulating structure is initially formed as insulating lines running in parallel along said second direction, and wherein, after providing said lines of said first dielectric layer stack, said insulating regions are formed by removing uncovered parts of said insulating structure, thereby forming recess regions within said semiconductor substrate.

28. The method of claim 27, wherein said doped semiconductor zones, constituting source/drain regions of said non-volatile memory cell array, are formed by implanting dopants into said semiconductor substrate.

29. The method of claim 28, wherein said dopants are implanted at a stage where said parallel lines of said second conductive layer are already provided and before said second insulating coating structure is completed.

30. The method of claim 24, wherein said insulating coating structures are formed of nitride.

31. The method of claim 30, wherein a material of said insulating regions is chosen as an oxide of silicon.

32. The method of claim 31, wherein said first and second conductive regions, constituting first and second wordlines, are formed of doped polycrystalline silicon.

33. The method of claim 32, wherein said first and second dielectric layer stacks are formed as ONO layer stacks constituting charge storage regions of said non-volatile memory cells.
